(19) United States
(12) Patent Application Publication
(10) Pub. No.: US 2024/0414999 A1
(43) Pub. Date: Dec. 12, 2024

(54) MANUFACTURING METHOD AND MANUFACTURING EQUIPMENT OF DISPLAY DEVICE

(71) Applicant: Japan Display Inc., Tokyo (JP)

(72) Inventors: Masaru TAKAYAMA, Tokyo (JP); Kaichi FUKUDA, Tokyo (JP); Takanobu TAKENAKA, Tokyo (JP); Hirofumi MIZUKOSHI, Tokyo (JP); Yuki HAMADA, Tokyo (JP)

(73) Assignee: Japan Display Inc., Tokyo (JP)

(21) Appl. No.: 18/677,944

(22) Filed: May 30, 2024

(30) Foreign Application Priority Data
Jun. 9, 2023 (JP) 2023-095512

(51) Int. Cl. H10K 71/16; H10K 71/60

(52) U.S. Cl. CPC H10K 71/164; H10K 71/60

(57) ABSTRACT

According to one embodiment, a manufacturing method includes preparing a substrate with a lower electrode, a rib and a partition, and forming an organic layer and an upper electrode. A first evaporation source used to form a first thin film of the organic layer includes a first nozzle emitting a material toward the substrate relatively moving. A second evaporation source used to form the upper electrode includes a second nozzle emitting a material toward the substrate relatively moving. An axis of at least one of the nozzles inclines to a direction orthogonal to a moving direction of the substrate with respect to a normal direction.

### CROSS-REFERENCE TO RELATED APPLICATION

This application is based upon and claims the benefit of priority from Japanese Patent Application No. 2023-095512, filed Jun. 9, 2023, the entire contents of which are incorporated herein by reference.

### FIELD

Embodiments described herein relate generally to a manufacturing method and a manufacturing equipment of a display device.

### BACKGROUND

Recently, display devices to which an organic light emitting diode (OLED) is applied as a display element have been put into practical use. This display element comprises a lower electrode, an organic layer which covers the lower electrode, and an upper electrode which covers the organic layer. Common voltage is applied to the upper electrode of each display element through lines provided in a display area.

The organic layer and the upper electrode are formed by vapor deposition relative to a substrate on which the lines described above are provided. In this case, there is a possibility that the connection between the upper electrode and the lines is interrupted by the organic layer which is formed earlier.

### BRIEF DESCRIPTION OF THE DRAWINGS

FIG. 1 is a diagram showing a configuration example of a display device according to an embodiment.

FIG. 2 is a schematic plan view showing an example of the layout of subpixels.

FIG. 3 is a schematic cross-sectional view of the display device along the III-III line of FIG. 2.

FIG. 4 is a diagram showing an example of a layer structure which could be applied to an organic layer.

FIG. 5 is a schematic cross-sectional view of the display device along the V-V line of FIG. 2.

FIG. 6 is a schematic plan view of a partition which surrounds subpixels.

FIG. 7 is a flowchart showing an example of the manufacturing method of the display device.

FIG. 8A is a schematic cross-sectional view showing the manufacturing process of the display device.

FIG. 8B is a schematic cross-sectional view showing a manufacturing process following FIG. 8A.

FIG. 8C is a schematic cross-sectional view showing a manufacturing process following FIG. 8B.

FIG. 8D is a schematic cross-sectional view showing a manufacturing process following FIG. 8C.

FIG. 8E is a schematic cross-sectional view showing a manufacturing process following FIG. 8D.

FIG. 8F is a schematic cross-sectional view showing a manufacturing process following FIG. 8E.

FIG. 8G is a schematic cross-sectional view showing a manufacturing process following FIG. 8F.

FIG. 9 is a diagram showing the schematic configuration of part of the manufacturing equipment of the display device.

FIG. 10 is a schematic plan view showing an example of the relationship between a substrate which is conveyed and an evaporation source.

FIG. 11 is a schematic perspective view showing an example of a configuration which can be applied to the evaporation source of a hole injection layer.

FIG. 12 is a schematic perspective view showing another example of a configuration which can be applied to the evaporation source of a hole injection layer.

FIG. 13 is a schematic perspective view showing an example of a configuration which can be applied to the evaporation sources of a hole transport layer, an electron blocking layer, a light emitting layer, a hole blocking layer, an electron transport layer and an electron injection layer.

FIG. 14 is a schematic perspective view showing an example of a configuration which can be applied to the evaporation source of an upper electrode.

FIG. 15 is a schematic cross-sectional view showing the process of forming a hole injection layer.

FIG. 16 is a schematic cross-sectional view showing the process of forming a hole transport layer, an electron blocking layer, a light emitting layer, a hole blocking layer, an electron transport layer and an electron injection layer.

FIG. 17 is a schematic cross-sectional view showing the process of forming an upper electrode.

FIG. 18 is a diagram showing another example of the process of forming an upper electrode.

FIG. 19 is a schematic cross-sectional view showing the first modified example of a configuration which could be applied to the partition.

FIG. 20 is a schematic cross-sectional view showing the second modified example of a configuration which could be applied to the partition.

### DETAILED DESCRIPTION

In general, according to one embodiment, a manufacturing method of a display device includes preparing a substrate including a lower electrode, a rib having a pixel aperture which overlaps the lower electrode, and a partition having a conductive lower portion provided on the rib and an upper portion which protrudes from a side surface of the lower portion, forming an organic layer which is in contact with the lower electrode through the pixel aperture and emits light based on application of voltage by vapor deposition for the substrate, and forming an upper electrode which covers the organic layer and is in contact with the lower portion of the partition by vapor deposition for the substrate. The organic layer includes a first thin film. A first evaporation source used to form the first thin film comprises a first nozzle which emits a vaporized material toward the substrate which relatively moves with respect to the first evaporation source. A second evaporation source used to form the upper electrode comprises a second nozzle which emits a vaporized material toward the substrate which relatively moves with respect to the second evaporation source. Further, an axis of at least one of the first nozzle and the second nozzle inclines to a direction orthogonal to a moving direction of the substrate in plan view with respect to a normal direction of the substrate.

According to another embodiment, a manufacturing equipment of a display device comprises a first evaporation device which forms, for a substrate including a lower electrode, a rib having a pixel aperture which overlaps the lower electrode, and a partition having a conductive lower portion provided on the rib and an upper portion which protrudes from a side surface of the lower portion, an organic layer which is in contact with the lower electrode through the pixel aperture and emits light based on application of voltage, and a second evaporation device which forms an upper electrode which covers the organic layer and is in contact with the lower portion of the partition for the substrate. The organic layer includes a first thin film. The first evaporation device comprises a first evaporation source comprising a first nozzle which emits a vaporized material of the first thin film toward the substrate which relatively moves with respect to the first evaporation source. The second evaporation device comprises a second evaporation source comprising a second nozzle which emits a vaporized material of the upper electrode toward the substrate which relatively moves with respect to the second evaporation source. Further, an axis of at least one of the first nozzle and the second nozzle inclines to a direction orthogonal to a moving direction of the substrate in plan view with respect to a normal direction of the substrate.

The embodiments can provide a manufacturing method and a manufacturing equipment of a display device in which lines provided in a display area can be satisfactorily connected to the upper electrode of each display element.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

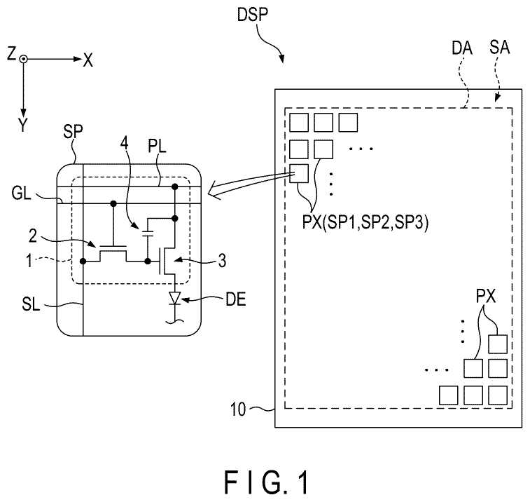

FIG. 1 is a diagram showing a configuration example of a display device DSP according to an embodiment. The display device DSP comprises an insulating substrate 10. The substrate 10 has a display area DA which displays an image, and a surrounding area SA around the display area DA. The substrate 10 may be glass or a resinous film having flexibility.

In the embodiment, the substrate 10 is rectangular as seen in plan view. It should be noted that the shape of the substrate 10 in plan view is not limited to a rectangle and may be another shape such as a square, a circle or an oval.

The display area DA comprises a plurality of pixels PX arrayed in matrix in an X-direction and a Y-direction. Each pixel PX includes a plurality of subpixels SP which display different colors. This embodiment assumes a case where each pixel PX includes a blue subpixel SP1, a green subpixel SP2 and a red subpixel SP3. However, each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

A plurality of scanning lines GL which supply a scanning signal to the pixel circuit 1 of each subpixel SP, a plurality of signal lines SL which supply a video signal to the pixel circuit 1 of each subpixel SP and a plurality of power lines PL are provided in the display area DA. In the example of FIG. 1, the scanning lines GL and the power lines PL extend in the X-direction, and the signal lines SL extend in the Y-direction.

The gate electrode of the pixel switch 2 is connected to the scanning line GL. One of the source electrode and drain electrode of the pixel switch 2 is connected to the signal line SL. The other one is connected to the gate electrode of the drive transistor 3 and the capacitor 4. In the drive transistor 3, one of the source electrode and the drain electrode is connected to the power line PL and the capacitor 4, and the other one is connected to the display element DE.

It should be noted that the configuration of the pixel circuit 1 is not limited to the example shown in the figure. For example, the pixel circuit 1 may comprise more thin-film transistors and capacitors.

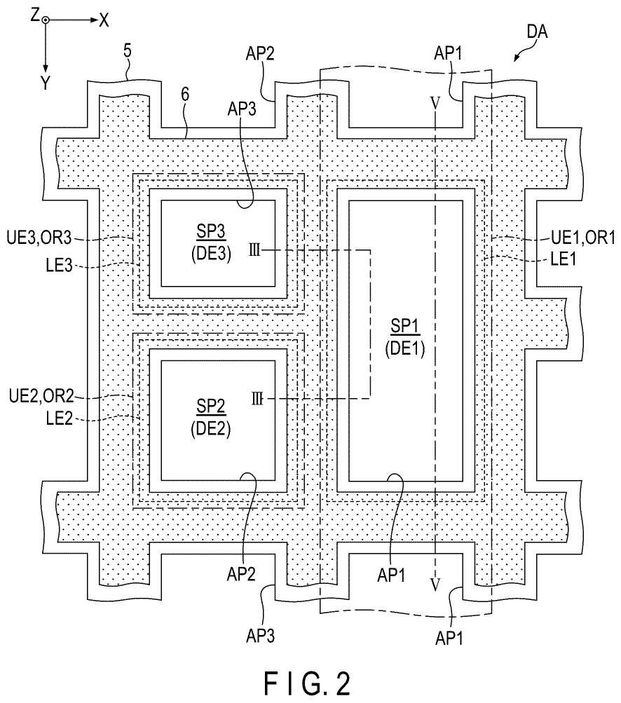

FIG. 2 is a schematic plan view showing an example of the layout of subpixels SP1, SP2 and SP3. In the example of FIG. 2, each of subpixels SP2 and SP3 is adjacent to subpixel SP1 in the X-direction. Further, subpixels SP2 and SP3 are arranged in the Y-direction.

When subpixels SP1, SP2 and SP3 are provided in line with this layout, a column in which subpixels SP2 and SP3 are alternately provided in the Y-direction and a column in which a plurality of subpixels SP1 are repeatedly provided in the Y-direction are formed in the display area DA. These columns are alternately arranged in the X-direction. It should be noted that the layout of subpixels SP1, SP2 and SP3 is not limited to the example of FIG. 2.

A rib 5 is provided in the display area DA. The rib 5 has pixel apertures AP1, AP2 and AP3 in subpixels SP1, SP2 and SP3, respectively. In the example of FIG. 2, the pixel aperture AP1 is larger than the pixel aperture AP2. The pixel aperture AP2 is larger than the pixel aperture AP3. Thus, among subpixels SP1, SP2 and SP3, the aperture ratio of subpixel SP1 is the greatest, and the aperture ratio of subpixel SP3 is the least.

Subpixel SP1 comprises a lower electrode LE1, an upper electrode UE1 and an organic layer OR1 overlapping the pixel aperture AP1. Subpixel SP2 comprises a lower electrode LE2, an upper electrode UE2 and an organic layer OR2 overlapping the pixel aperture AP2. Subpixel SP3 comprises a lower electrode LE3, an upper electrode UE3 and an organic layer OR3 overlapping the pixel aperture AP3.

Of the lower electrode LE1, the upper electrode UE1 and the organic layer OR1, the portions which overlap the pixel aperture API constitute the display element DE1 of subpixel SP1. Of the lower electrode LE2, the upper electrode UE2 and the organic layer OR2, the portions which overlap the pixel aperture AP2 constitute the display element DE2 of subpixel SP2. Of the lower electrode LE3, the upper electrode UE3 and the organic layer OR3, the portions which overlap the pixel aperture AP3 constitute the display element DE3 of subpixel SP3. Each of the display elements DE1, DE2 and DE3 may further include a cap layer as described later. The rib 5 surrounds each of these display elements DE1, DE2 and DE3.

A conductive partition 6 is provided on the rib 5. The partition 6 overlaps the rib 5 as a whole and has the same planar shape as the rib 5. In other words, the partition 6 has an aperture in each of subpixels SP1, SP2 and SP3. From another viewpoint, each of the rib 5 and the partition 6 has a grating shape as seen in plan view and surrounds each of subpixels SP1, SP2 and SP3. The partition 6 functions as lines which apply common voltage to the upper electrodes UE1, UE2 and UE3.

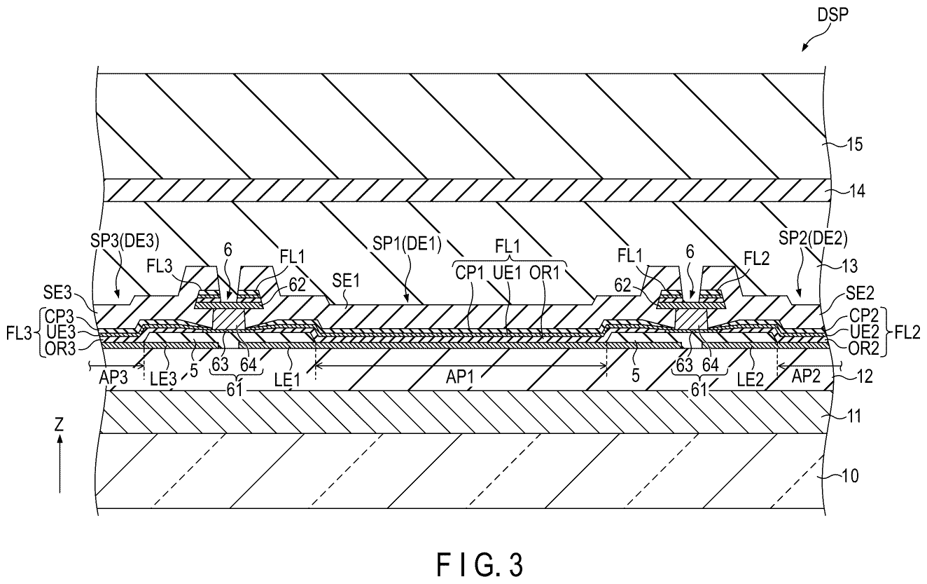

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuits 1, scanning lines GL, signal lines SL and power lines PL shown in FIG. 1. The circuit layer 11 is covered with an organic insulating layer 12. The organic insulating layer 12 functions as a planarization film which planarizes the irregularities formed by the circuit layer 11.

The lower electrodes LE1, LE2 and LE3 are provided on the organic insulating layer 12. The rib 5 is provided on the organic insulating layer 12 and the lower electrodes LE1, LE2 and LE3. The end portions of the lower electrodes LE1, LE2 and LE3 are covered with the rib 5. Although not shown in the section of FIG. 3, the lower electrodes LE1, LE2 and LE3 are connected to the respective pixel circuits 1 of the circuit layer 11 through respective contact holes provided in the organic insulating layer 12.

The partition 6 includes a conductive lower portion 61 provided on the rib 5 and an upper portion 62 provided on the lower portion 61. The upper portion 62 has a width greater than that of the lower portion 61. By this configuration, the both end portions of the upper portion 62 protrude relative to the side surfaces of the lower portion 61. This shape of the partition 6 is called an overhang shape.

In the example of FIG. 3, the lower portion 61 has a bottom layer 63 provided on the rib 5, and a stem layer 64 provided on the bottom layer 63. For example, the bottom layer 63 is formed so as to be thinner than the stem layer 64. In the example of

FIG. 3, the both end portions of the bottom layer 63 protrude from the side surfaces of the stem layer 64.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2 and UE3 are in contact with the side surfaces of the lower portions 61 of the partition 6.

The display element DE1 includes a cap layer CP1 provided on the upper electrode UE1. The display element DE2 includes a cap layer CP2 provided on the upper electrode UE2. The display element DE3 includes a cap layer CP3 provided on the upper electrode UE3. The cap layers CP1, CP2 and CP3 function as optical adjustment layers which improve the extraction efficiency of the light emitted from the organic layers OR1, OR2 and OR3, respectively.

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

The stacked film FL1 is partly located on the upper portion 62. This portion is spaced apart from, of the stacked film FL1, the portion located under the partition 6 (in other words, the portion which constitutes the display element DE1). Similarly, the stacked film FL2 is partly located on the upper portion 62. This portion is spaced apart from, of the stacked film FL2, the portion located under the partition 6 (in other words, the portion which constitutes the display element DE2). Further, the stacked film FL3 is partly located on the upper portion 62. This portion is spaced apart from, of the stacked film FL3, the portion located under the partition 6 (in other words, the portion which constitutes the display element DE3).

Sealing layers SE1, SE2 and SE3 are provided in subpixels SP1, SP2 and SP3, respectively. The sealing layer SE1 continuously covers the cap layer CP1 and the partition 6 around subpixel SP1. The sealing layer SE2 continuously covers the cap layer CP2 and the partition 6 around subpixel SP2. The sealing layer SE3 continuously covers the cap layer CP3 and the partition 6 around subpixel SP3.

In the example of FIG. 3, the stacked film FL1 and sealing layer SE1 located on the partition 6 between subpixels SP1 and SP2 are spaced apart from the stacked film FL2 and sealing layer SE2 located on this partition 6. The stacked film FL1 and sealing layer SE1 located on the partition 6 between subpixels SP1 and SP3 are spaced apart from the stacked film FL3 and sealing layer SE3 located on this partition 6.

The sealing layers SE1, SE2 and SE3 are covered with a resin layer 13. The resin layer 13 is covered with a sealing layer 14. The sealing layer 14 is covered with a resin layer 15. The resin layers 13 and 15 and the sealing layer 14 are continuously provided in at least the entire display area DA and partly extend in the surrounding area SA as well.

A cover member such as a polarizer, a touch panel, a protective film or a cover glass may be further provided above the resin layer 15. This cover member may be attached to the resin layer 15 via, for example, an adhesive layer such as an optical clear adhesive (OCA).

The organic insulating layer 12 is formed of an organic insulating material such as polyimide. Each of the rib 5 and the sealing layers 14, SE1, SE2 and SE3 is formed of an inorganic insulating material such as silicon nitride (SiNx), silicon oxide (SiOx), silicon oxynitride (SiON) or aluminum oxide (Al₂O₃).

For example, the rib 5 is formed of silicon oxynitride, and each of the sealing layers 14, SE1, SE2 and SE3 is formed of silicon nitride. Each of the resin layers 13 and 15 is formed of, for example, a resinous material (organic insulating material) such as epoxy resin or acrylic resin.

Each of the lower electrodes LE1, LE2 and LE3 has a reflective layer formed of, for example, silver, and a pair of conductive oxide layers covering the upper and lower surfaces of the reflective layer. Each of the conductive oxide layers can be formed of, for example, a transparent conductive oxide such as indium tin oxide (ITO), indium zinc oxide (IZO) or indium gallium zinc oxide (IGZO).

Each of the upper electrodes UE1, UE2 and UE3 is formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

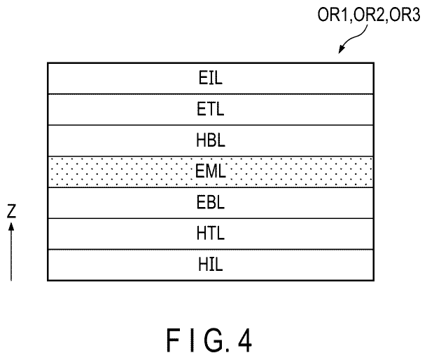

FIG. 4 is a diagram showing an example of a layer structure which could be applied to the organic layers OR1, OR2 and OR3. Each of the organic layers OR1, OR2 and OR3 is formed of a plurality of thin films including a light emitting layer EML. This embodiment assumes a case where each of the organic layers OR1, OR2 and OR3 comprises a structure in which a hole injection layer HIL, a hole transport layer HTL, an electron blocking layer EBL, a light emitting layer EML, a hole blocking layer HBL, an electron transport layer ETL and an electron injection layer EIL are stacked in order in a Z-direction. It should be noted that each of the organic layers OR1, OR2 and OR3 may comprise another structure such as a tandem structure including a plurality of light emitting layers EML.

Each of the cap layers CP1, CP2 and CP3 comprises, for example, a multilayer structure in which a plurality of transparent layers are stacked. These transparent layers could include a layer formed of an inorganic material and a layer formed of an organic material. The transparent layers have refractive indices different from each other. For example, the refractive indices of these transparent layers are different from the refractive indices of the upper electrodes UE1, UE2 and UE3 and the refractive indices of the sealing layers SE1, SE2 and SE3. It should be noted that at least one of the cap layers CP1, CP2 and CP3 may be omitted.

Each of the bottom layer 63 and stem layer 64 of the partition 6 is formed of a metal material. For the metal material of the bottom layer 63, for example, molybdenum, titanium, titanium nitride (TiN), a molybdenum-tungsten alloy (MoW) or a molybdenum-niobium alloy (MoNb) can be used. For the metal material of the stem layer 64, for example, aluminum, an aluminum-neodymium alloy (AlNd), an aluminum-yttrium alloy (AlY) or an aluminum-silicon alloy (AlSi) can be used. It should be noted that the stem layer 64 may be formed of an insulating material.

For example, the upper portion 62 of the partition 6 comprises a multilayer structure consisting of a lower layer formed of a metal material and an upper layer formed of conductive oxide. For the metal material forming the lower layer, for example, titanium, titanium nitride, molybdenum, tungsten, a molybdenum-tungsten alloy or a molybdenum-niobium alloy can be used. For the conductive oxide forming the upper layer, for example, ITO or IZO can be used. It should be noted that the upper portion 62 may comprise a single-layer structure of a metal material. The upper portion 62 may further include a layer formed of an insulating material.

Common voltage is applied to the partition 6. This common voltage is applied to each of the upper electrodes UE1, UE2 and UE3 which are in contact with the side surfaces of the lower portions 61. Pixel voltage is applied to the lower electrodes LE1, LE2 and LE3 through the pixel circuits 1 provided in subpixels SP1, SP2 and SP3, respectively, based on the video signals of the signal lines SL.

The organic layers OR1, OR2 and OR3 emit light based on the application of voltage. Specifically, when a potential difference is formed between the lower electrode LE1 and the upper electrode UE1, the light emitting layer EML of the organic layer OR1 emits light in a blue wavelength range. When a potential difference is formed between the lower electrode LE2 and the upper electrode UE2, the light emitting layer EML of the organic layer OR2 emits light in a green wavelength range. When a potential difference is formed between the lower electrode LE3 and the upper electrode UE3, the light emitting layer EML of the organic layer OR3 emits light in a red wavelength range.

As another example, the light emitting layers EML of the organic layers OR1, OR2 and OR3 may emit light exhibiting the same color (for example, white). In this case, the display device DSP may comprise color filters which convert the light emitted from the light emitting layers EML into light exhibiting colors corresponding to subpixels SP1, SP2 and SP3. The display device DSP may comprise a layer including quantum dots which generate light exhibiting colors corresponding to subpixels SP1, SP2 and SP3 by the excitation caused by the light emitted from the light emitting layers EML.

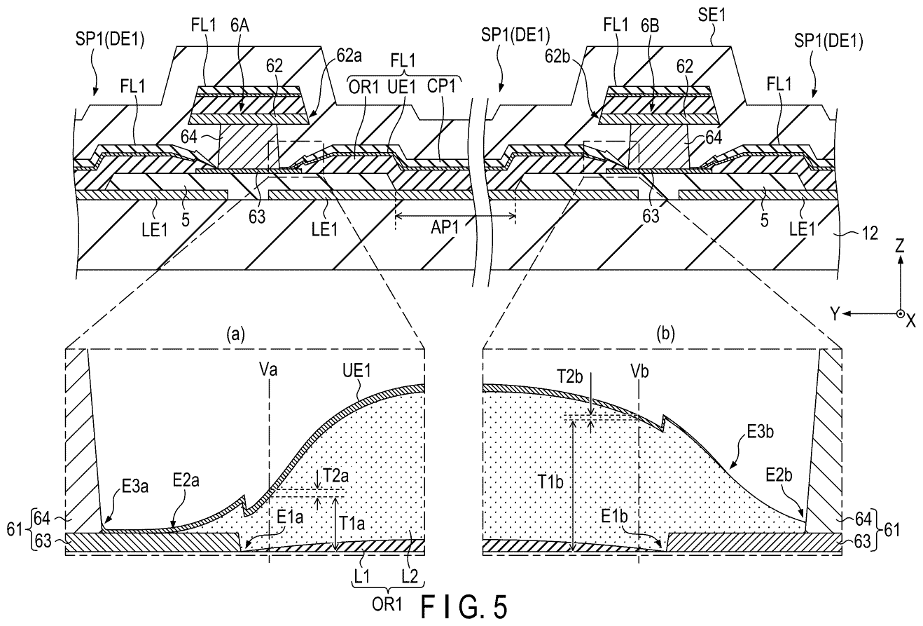

FIG. 5 is a schematic cross-sectional view of the display device DSP along the V-V line of FIG. 2. In this figure, the section corresponds to a Y-Z section defined by the Y-direction and the Z-direction and shows three subpixels SP1 arranged in the Y-direction. It should be noted that the substrate 10, the circuit layer 11, the resin layer 13, the sealing layer 14 and the resin layer 15 are omitted. In the following explanation, the partition 6 located on the left side of FIG. 5 is referred to as a first partition 6A, and the partition 6 located on the right side is referred to as a second partition 6B. These partitions 6A and 6B are provided such that the pixel aperture AP1 located in the middle of FIG. 5 is interposed between them in the Y-direction.

In the example of FIG. 5, the stacked film FL1 and the sealing layer SE are continuous on the partitions 6A and 6B. In other words, the sealing layer SE1 continuously covers the partitions 6A and 6B and the cap layer CP1 of each subpixel SP1.

As shown in the enlarged views(a) and(b) of FIG. 5, the organic layer OR1 has a first layer L1 and a second layer L2 provided on the first layer L1. This embodiment assumes the following case. The first layer L1 consists of a hole injection layer HIL, and the second layer L2 consists of a hole transport layer HTL, an electron blocking layer EBL, a light emitting layer EML, a hole blocking layer HBL, an electron transport layer ETL and an electron injection layer EIL. It should be noted that the first layer L1 may further include another layer such as a hole transport layer HTL in addition to the hole injection layer HIL. In FIG. 5(a) and FIG. 5(b), the cap layer CP1 and the sealing layer SE1 are omitted.

The thicknesses of the first layer L1 and the second layer L2 decrease toward the partitions 6A and 6B. Similarly, the thickness of the upper electrode UE1 decreases toward the partitions 6A and 6B.

The first layer L1 has an end portion E1a located on the first partition 6A side, and an end portion E1b located on the second partition 6B side. To prevent the generation of leak current between the organic layer OR1 and the partitions 6A and 6B, it is preferable that the hole injection layer HIL forming the first layer L1 should not be electrically connected to the partition 6. In other words, as shown in FIG. 5, the end portions E1a and E1b should be preferably spaced apart from the bottom layers 63 of the partitions 6A and 6B, respectively. However, the first layer L1 may be slightly in contact with at least one of these bottom layers 63.

The second layer L2 has an end portion E2a located on the first partition 6A side, and an end portion E2b located on the second partition 6B side.

In the example of FIG. 5(a) and FIG. 5(b), the end portions E2a and E2b are located on the bottom layers 63 of the partitions 6A and 6B, respectively. In other words, the second layer L2 is in contact with the bottom layers 63 of the partitions 6A and 6B. As another example, the second layer L2 may not be in contact with the bottom layer 63 of the first partition 6A. Further, the second layer L2 may be in contact with neither the bottom layer 63 of the partition 6A nor the bottom layer 63 of the partition 6B.

As shown in FIG. 5(a), the end portion E2a is spaced apart from the stem layer 64 of the first partition 6A. By this structure, an area which is not covered with the second layer L2 is formed on the upper surface of the bottom layer 63 of the first partition 6A. To the contrary, in the example of FIG. 5(b), the end portion E2b is in contact with the stem layer 64 of the second partition 6B. By this structure, the upper surface of the bottom layer 63 of the second partition 6B is entirely covered with the second layer L2. As another example, the end portion E2b may be spaced apart from the stem layer 64 of the second partition 6B.

The upper electrode UE1 has an end portion E3a located on the first partition 6A side, and an end portion E3b located on the second partition 6B side. In the example of FIG. 5(a), the end portion E3a is located on the bottom layer 63 of the first partition 6A and is further in contact with the stem layer 64. It should be noted that the end portion E3a may be spaced apart from the stem layer 64. To the contrary, in the example of FIG. 5(b), the end portion E3b is located on the second layer L2 and is not in contact with the bottom layer 63 or the stem layer 64 of the second partition 6B. As another example, the end portion E3b may be in contact with the stem layer 64 of the second partition 6B.

Line segment Va shown by the chained line in FIG. 5(a) is a straight line which passes through the first end portion 62a of the upper portion 62 of the first partition 6A and is parallel to the Z-direction. Line segment Vb shown by the chained line in FIG. 5(b) is a straight line which passes through the second end portion 62b of the upper portion 62 of the second partition 6B and is parallel to the Z-direction.

The organic layer OR1 has thickness T1a at the position intersecting with line segment Va, that is, immediately under the first end portion 62a. The organic layer OR1 has thickness T1b at the position intersecting with line segment Vb, that is, immediately under the second end portion 62b. Each of thicknesses T1a and T1b corresponds to the total thickness of the first layer L1 and the second layer L2.

The upper electrode UE1 has thickness T2a at the position intersecting with line segment Va, that is, immediately under the first end portion 62a. The upper electrode UE1 has thickness T2b at the position intersecting with line segment Vb, that is, immediately under the second end portion 62b. For example, thickness T2a is less than thickness T1a (T2a<T1a). Thickness T2b is less than thickness T1b (T2b<T1b).

In the embodiment, thickness T1a is less than thickness T1b (T1a<T1b). Further, thickness T2a is greater than thickness T2b (T2a>T2b). Thus, the organic layer OR1 is formed so as to be thin near the first partition 6A and thick near the second partition 6B. The upper electrode UE1 is formed so as to be thick near the first partition 6A and thin near the second partition 6B.

In the embodiment, the contact area of the lower portion 61 (the bottom layer 63 and the stem layer 64) of the first partition 6A and the organic layer OR1 is less than that of the lower portion 61 of the second partition 6B and the organic layer OR1.

Further, the contact area of the lower portion 61 of the first partition 6A and the upper electrode UE1 is greater than that of the lower portion 61 of the second partition 6B and the upper electrode UE1. In the example of FIG. 5(b), the upper electrode UE1 is not in contact with the lower portion 61 of the second partition 6B. In this case, the contact area of the lower portion 61 of the second partition 6B and the upper electrode UE1 is zero. The configuration is not limited to this example. The contact area may not be zero as the upper electrode UE1 is in contact with the bottom layer 63 and stem layer 64 of the second partition 6B.

Thus, in the example of FIG. 5, the contact area of the bottom layer 63 of the first partition 6A and the upper electrode UE1 is made large by forming the organic layer OR1 so as to be thin and further forming the upper electrode UE1 so as to be thick near the first partition 6A. By this configuration, the upper electrode UE1 can be satisfactorily electrically connected to the partition 6.

It should be noted that each subpixel SP1 provided in the display area DA has the same shape as subpixel SP1 shown in the middle of FIG. 5. Specifically, when each of the partitions 6A and 6B is particularly looked at, the vicinity of a side surface of the lower portion 61 comprises the structure of FIG. 5(a), and the vicinity of the other side surface comprises the structure of FIG. 5(b).

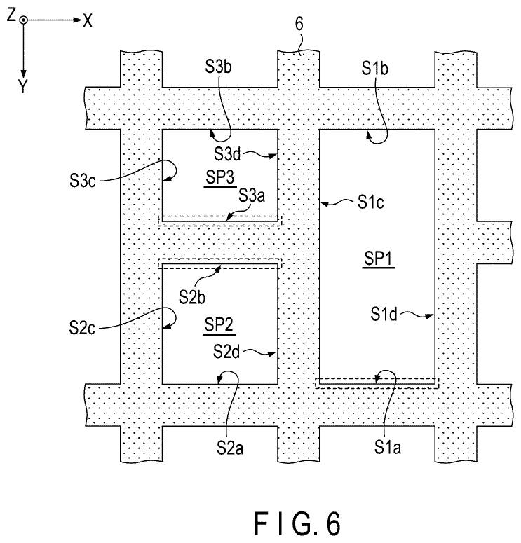

FIG. 6 is a schematic plan view of the partition 6 which surrounds subpixels SP1, SP2 and SP3. As shown in the figure, the four sides of the partition 6 which surrounds subpixel SP1 are defined as sides S1a, S1b, S1c and S1d. The four sides of the partition 6 which surrounds subpixel SP2 are defined as sides S2a, S2b, S2c and S2d. The four sides of the partition 6 which surrounds subpixel SP3 are defined as sides S3a, S3b, S3c and S3d. The sides S1a, S1b, S2a, S2b, S3a and S3b are parallel to the X-direction. The sides S1c, S1d, S2c, S2d, S3c and S3d are parallel to the Y-direction.

The sides S1a, S2b and S3a surrounded by the chained frames correspond to contact sides on which the respective upper electrodes UE1, UE2 and UE3 are in contact with the partition 6. Common voltage is applied to the upper electrodes UE1, UE2 and UE3 through at least these contact sides.

The structure of the side S1a is as shown in FIG. 5(a). The structure of the organic layer OR2, the upper electrode UE2 and the partition 6 in the side S2b is similar to that of the organic layer OR1, the upper electrode UE1 and the first partition 6A shown in FIG. 5(a). Further, the structure of the organic layer OR3, the upper electrode UE3 and the partition 6 in the side S3a is similar to that of the organic layer OR1, the upper electrode UE1 and the first partition 6A shown in FIG. 5(a). By this configuration, the upper electrodes UE2 and UE3 can be satisfactorily electrically connected to the partition 6 in a manner similar to that of the upper electrode UE1.

The structure of the side Slb is as shown in FIG. 5(b). The structure of the organic layer OR2, the upper electrode UE2 and the partition 6 in the side S2a is similar to that of the organic layer OR1, the upper electrode UE1 and the second partition 6B shown in FIG. 5(b). Further, the structure of the organic layer OR3, the upper electrode UE3 and the partition 6 in the side S3b is similar to that of the organic layer OR1, the upper electrode UE1 and the second partition 6B shown in FIG. 5(b).

It should be noted that the upper electrodes UE1, UE2 and UE3 may be in contact with the lower portion 61 in other sides in addition to the contact sides shown in the figure. In addition, the position of the contact side of subpixel SP1, SP2 or SP3 is not limited to the example of FIG. 6 and may be appropriately modified.

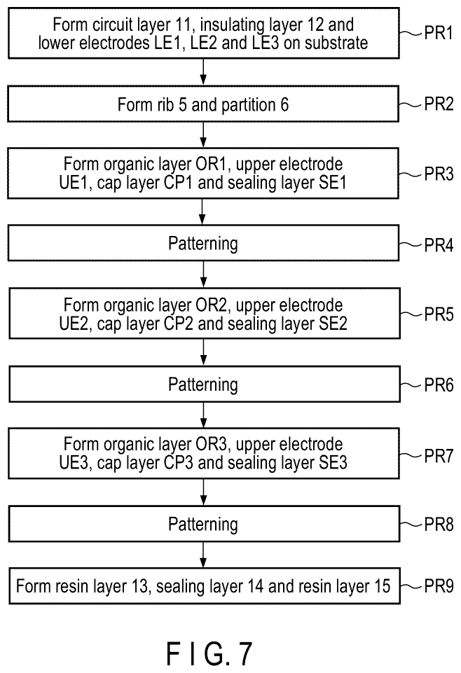

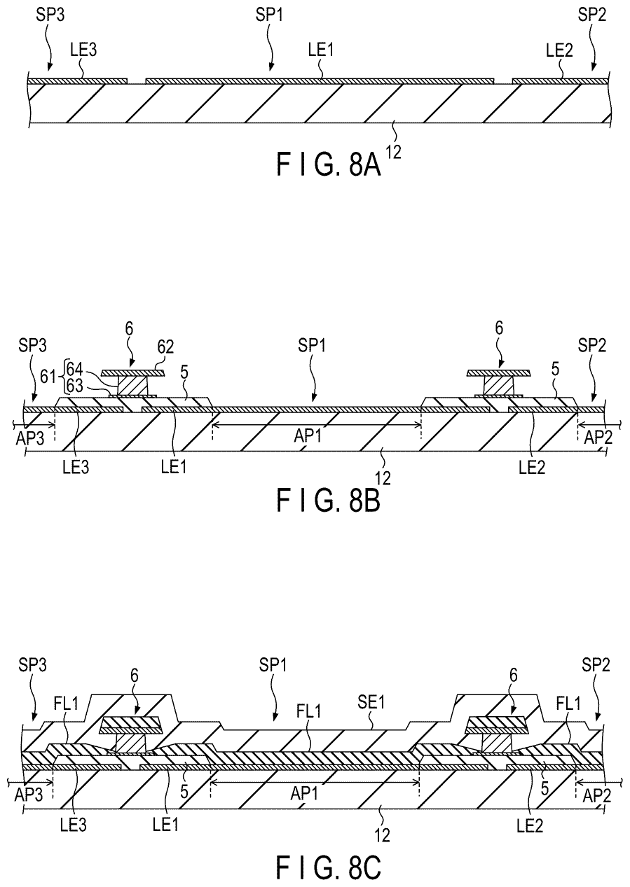

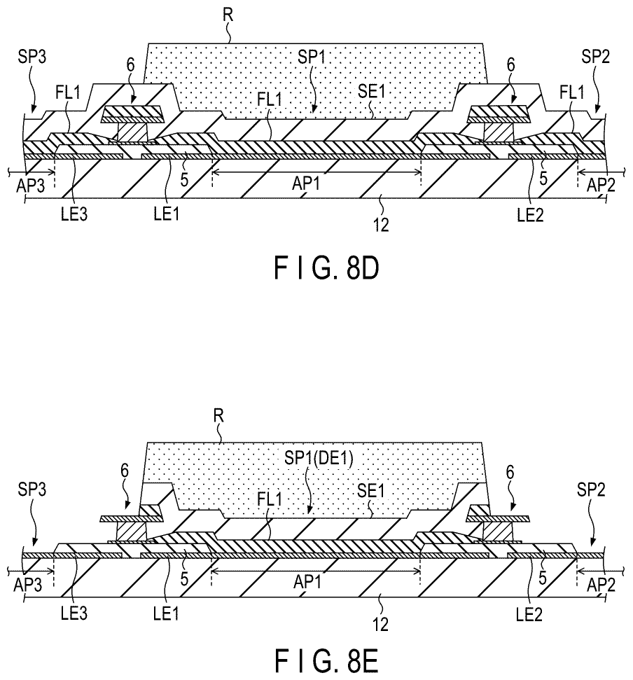

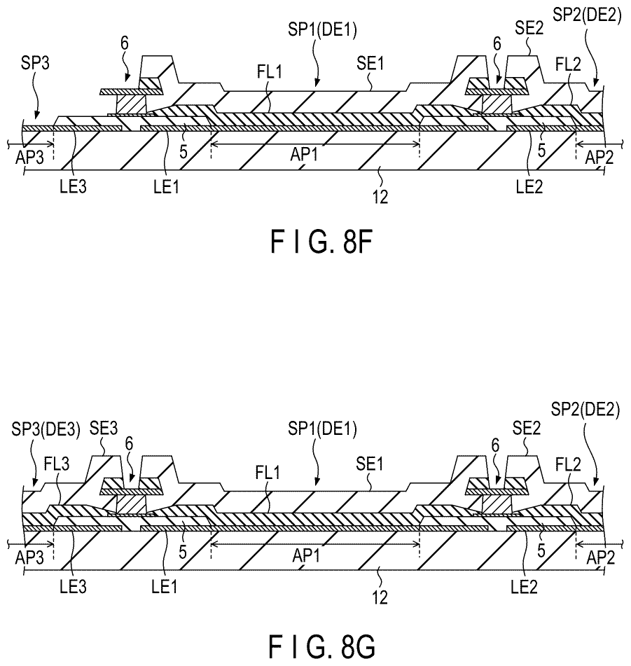

FIG. 7 is a flowchart showing an example of the manufacturing method of the display device DSP. Each of FIG. 8A to FIG. 8G is a schematic cross-sectional view showing the manufacturing process of the display device DSP. In FIG. 8A to FIG. 8G, the illustrations of the substrate 10 and the circuit layer 11 are omitted.

To manufacture the display device DSP, first, the circuit layer 11 and the organic insulating layer 12 are formed on the substrate 10, and further, the lower electrodes LE1, LE2 and LE3 are formed on the organic insulating layer 12 as shown in FIG. 8A (process PR1).

Subsequently, the rib 5 and the partition 6 are formed as shown in FIG. 8B (process PR2). The pixel apertures AP1, AP2 and AP3 of the rib 5 may be provided after the formation of the partition 6 or may be provided before the formation of the partition 6.

After preparing the substrate on which the lower electrodes LE1, LE2 and LE3, the rib 5 and the partition 6 are formed by processes PR1 and PR2, a process for forming the display elements DE1, DE2 and DE3 is performed. In the embodiment, this specification assumes a case where the display element

DE1 is formed firstly, and the display element DE2 is formed secondly, and the display element DE3 is formed lastly. It should be noted that the formation order of the display elements DE1, DE2 and DE3 is not limited to this example.

To form the display element DE1, first, as shown in FIG. 8C, the stacked film FL1 and the sealing layer SE1 are formed (process PR3). The stacked film FL1 includes, as shown in FIG. 3, the organic layer OR1 which is in contact with the lower electrode LE1 through the pixel aperture AP1, the upper electrode UE1 which covers the organic layer OR1 and the cap layer CP1 which covers the upper electrode UE1. The organic layer OR1, the upper electrode UE1 and the cap layer CP1 are formed by vapor deposition. The sealing layer SE1 is formed by chemical vapor deposition (CVD). The stacked film FL1 is divided into a plurality of portions by the partition 6 having an overhang shape. The sealing layer SE1 continuously covers the portions into which the stacked film FL1 is divided, and the partition 6.

After process PR3, the stacked film FL1 and the sealing layer SE1 are patterned (process PR4). In this patterning, as shown in FIG. 8D, a resist R is provided on the sealing layer SE1. The resist R covers subpixel SP1 and part of the partition 6 around the subpixel.

Subsequently, as shown in FIG. 8E, the portions of the stacked film FL1 and the sealing layer SE1 exposed from the resist R are removed by etching using the resist R as a mask. In other words, of the stacked film FL1 and the sealing layer SE1, the portions which overlap the lower electrode LE1 remain, and the other portions are removed. By this process, the display element DE1 is formed in subpixel SP1. For example, this etching includes wet etching and dry etching processes which are performed in order for the sealing layer SE1, the cap layer CP1, the upper electrode UE1 and the organic layer OR1. After these etching processes, the resist R is removed.

The display element DE2 is formed by a procedure similar to that of the display element DE1. Specifically, when the display element DE2 is formed, the stacked film FL2 and the sealing layer SE2 are formed in the entire display area DA (process PR5). The stacked film FL2 includes, as shown in FIG. 3, the organic layer OR2 which is in contact with the lower electrode LE2 through the pixel aperture AP2, the upper electrode UE2 which covers the organic layer OR2 and the cap layer CP2 which covers the upper electrode UE2.

The organic layer OR2, the upper electrode UE2 and the cap layer CP2 are formed by vapor deposition. The sealing layer SE2 is formed by CVD. The stacked film FL2 is divided into a plurality of portions by the partition 6 having an overhang shape. The sealing layer SE2 continuously covers the portions into which the stacked film FL2 is divided, and the partition 6.

After process PR5, the stacked film FL2 and the sealing layer SE2 are patterned (process PR6). By this process, the display element DE2 is formed in subpixel SP2 as shown in FIG. 8F.

The display element DE3 is formed by a procedure similar to the procedures of the display elements DE1 and DE2. Specifically, when the display element DE3 is formed, the stacked film FL3 and the sealing layer SE3 are formed in the entire display area DA (process PR7). The stacked film FL3 includes, as shown in FIG. 3, the organic layer OR3 which is in contact with the lower electrode LE3 through the pixel aperture AP3, the upper electrode UE3 which covers the organic layer OR3 and the cap layer CP3 which covers the upper electrode UE3.

The organic layer OR3, the upper electrode UE3 and the cap layer CP3 are formed by vapor deposition. The sealing layer SE3 is formed by CVD. The stacked film FL3 is divided into a plurality of portions by the partition 6 having an overhang shape. The sealing layer SE3 continuously covers the portions into which the stacked film FL3 is divided, and the partition 6.

After process PR7, the stacked film FL3 and the sealing layer SE3 are patterned (process PR8). By this process, the display element DE3 is formed in subpixel SP3 as shown in FIG. 8G.

After the display elements DE1, DE2 and DE3 are formed, the resin layer 13, sealing layer 14 and resin layer 15 shown in FIG. 3 are formed in order (process PR9). The display device DSP is completed through this process.

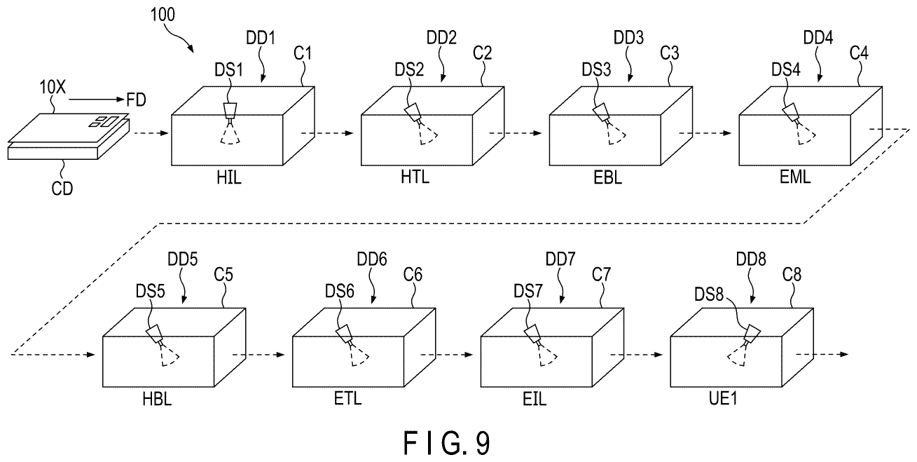

FIG. 9 is a diagram showing the schematic configuration of part of the manufacturing equipment 100 of the display device DSP. The manufacturing equipment 100 shown in the figure corresponds to a manufacturing line which forms the organic layer OR1 and the upper electrode UE1, and comprises evaporation devices DD1 to DD7 for forming the hole injection layer HIL, the hole transport layer HTL, the electron blocking layer EBL, the light emitting layer EML, the hole blocking layer HBL, the electron transport layer ETL and the electron injection layer EIL. The evaporation devices DD1 to DD7 constitute a first evaporation device for forming the organic layer OR1. The manufacturing equipment 100 further comprises an evaporation device DD8 (second evaporation device) for forming the upper electrode UE1.

The evaporation devices DD1 to DD8 comprise chambers C1 to C8 provided such that the inside is maintained as a vacuum, respectively, and evaporation sources DS1 to DS8 provided inside the chambers Cl to C8, respectively. Further, the manufacturing equipment 100 comprises a conveyance device CD which conveys a substrate 10X on which the partition 6 is formed through process PR2. The substrate 10X may be a mother substrate on which a plurality of panel portions each corresponding to the display device DSP are formed. The conveyance device CD conveys the substrate 10X to the chambers C1 to C8 in series. In the following explanation, the direction in which the substrate 10X passes through the chambers C1 to C8 (the direction in which the substrate 10X relatively moves with respect to the evaporation sources DS1 to DS8) is referred to as a moving direction FD.

It should be noted that FIG. 9 shows an example in which the manufacturing equipment 100 comprises the evaporation devices DD1 to DD7 by assuming a case where the organic layer OR1 comprises a configuration in which the hole injection layer HIL, the hole transport layer HTL, the electron blocking layer EBL, the light emitting layer EML, the hole blocking layer HBL, the electron transport layer ETL and the electron injection layer EIL are stacked in order. However, the configuration of the evaporation devices provided in the manufacturing equipment 100 could be modified based on the configuration of the thin films included in the organic layer OR1.

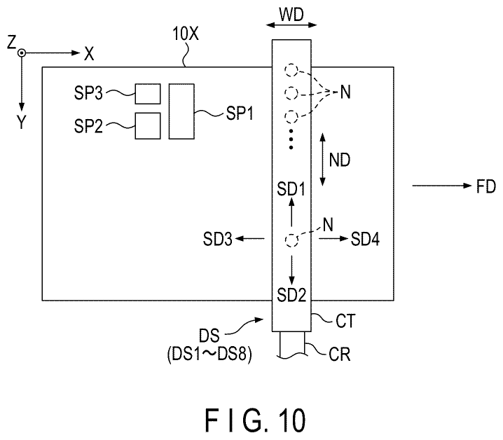

FIG. 10 is a schematic plan view showing an example of the relationship between the substrate 10X which is conveyed and an evaporation source DS (DS1 to DS8). The evaporation source DS comprises a crucible CR, a long container CT connected to the crucible CR, and a plurality of nozzles N provided in the container CT.

The crucible CR vaporizes (volatilizes or sublimates) the material accommodated in the crucible CR by heating the material. The vaporized material is supplied to the container CT and is emitted from each nozzle N toward the substrate 10X which relatively moves in the moving direction FD with respect to the evaporation source DS. The nozzles N are linearly arranged in a nozzle alignment direction ND on a surface of the container CT facing the substrate 10X.

For example, the substrate 10X is conveyed such that the moving direction FD is orthogonal to the nozzle alignment direction ND. In the example of FIG. 10, the width direction WD of the evaporation source DS orthogonal to the nozzle alignment direction ND, the moving direction FD and the X-direction are parallel to each other.

In the following explanation, a first lateral direction SD1, a second lateral direction SD2, a third lateral direction SD3 and a fourth lateral direction SD4 relative to the nozzle Z are defined as shown in FIG. 10. The first lateral direction SD1 and the second lateral direction SD2 are the opposite directions of each other and are parallel to nozzle alignment direction ND and the Y-direction in the example of FIG. 10. Thus, the first lateral direction SD1 and the second lateral direction SD2 are orthogonal to the moving direction FD as seen in plan view. The third lateral direction SD3 and the fourth lateral direction SD4 are the opposite directions of each other and are parallel to the moving direction FD, the width direction WD and the X-direction in the example of FIG. 10. The third lateral direction SD3 points to the upstream side in the moving direction FD. The fourth lateral direction SD4 points to the downstream side in the moving direction FD.

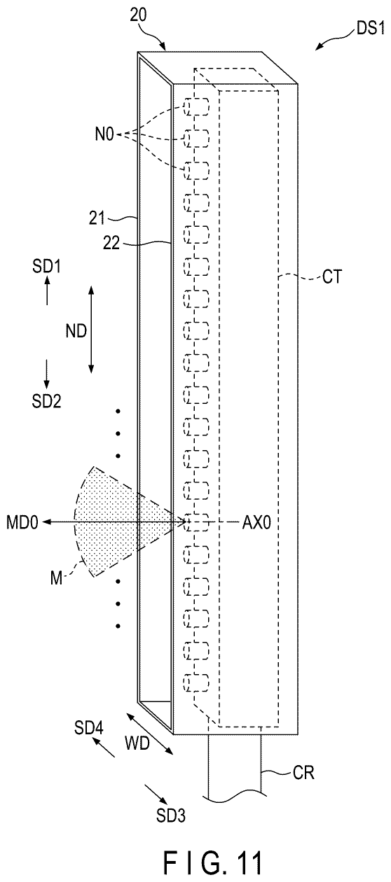

FIG. 11 is a schematic perspective view showing an example of a configuration which can be applied to the evaporation source DS1 of the hole injection layer HIL. In the following explanation, each nozzle N of the evaporation source DS1 is referred to as a nozzle N0. Each nozzle N0 emits the vaporized material M of the hole injection layer HIL in evaporation direction MD0.

Evaporation direction MD0 is, for example, parallel to axis AX0 of each nozzle N0 (the extension direction of each nozzle N0). In the example of FIG. 11, axis AX0 is orthogonal to the nozzle alignment direction ND and the width direction WD. The material M is emitted from each nozzle N0 with a predetermined spread angle based on evaporation direction MD0. Evaporation direction MD0 can be also regarded as a direction parallel to the central axis of the material M emitted from each nozzle N0, or the main emission direction of the material M.

The evaporation source DS1 may further comprise a shield 20 which surrounds the nozzles N. the example of FIG. 11, the shield 20 surrounds the container CT and each nozzle N0 and has a shape in which the nozzle N0 side is open.

The shield 20 has a first sidewall 21 and a second sidewall 22 in the width direction WD. These sidewalls 21 and 22 protrude relative to the distal end of each nozzle N0 in evaporation direction MD0 and prevent the material M from spreading in the width direction WD.

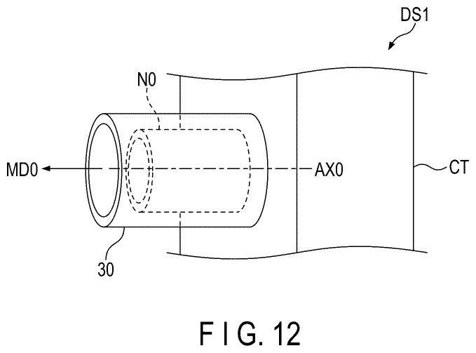

FIG. 12 is a schematic perspective view showing another example of a configuration which can be applied to the evaporation source DS1. In the example of this figure, a shield 30 is further provided relative to the nozzle N0. The shield 30 has, for example, a cylindrical shape which surrounds the nozzle N0, and is attached to the container CT. For example, the shield 30 is provided for each of the nozzles N0 of the evaporation source DS1.

The shield 30 protrudes in evaporation direction MD0 relative to the distal end of the nozzle N0. The height of the shield 30 (the protrusion length from the distal end of the nozzle N0) is uniform over the whole circumference of the nozzle N0. This configuration prevents the material M emitted from the nozzle N0 from spreading in all directions based on the nozzle N0.

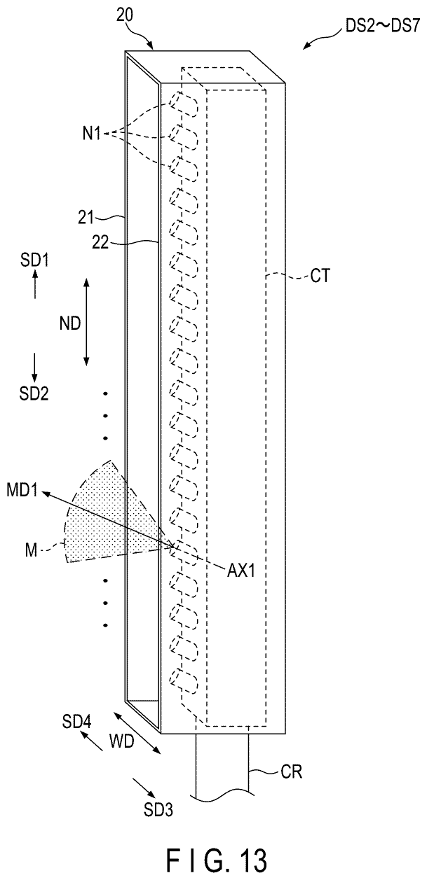

FIG. 13 is a schematic perspective view showing an example of a configuration which can be applied to the evaporation sources DS2 to DS7 of the hole transport layer HTL, the electron blocking layer EBL, the light emitting layer EML, the hole blocking layer HBL, the electron transport layer ETL and the electron injection layer EIL. In the following explanation, each nozzle N of the evaporation sources DS2 to DS7 is referred to as a nozzle N1. Each nozzle N1 emits the vaporized material M in evaporation direction MD1.

Evaporation direction MD1 is, for example, parallel to axis AX1 of each nozzle N1 (the extension direction of each nozzle N1). The material M is emitted from each nozzle N1 with a predetermined spread angle based on evaporation direction MD1. Evaporation direction MD1 can be also regarded as a direction parallel to the central axis of the material M emitted from each nozzle N1, or the main emission direction of the material M. In the example of FIG. 13, axis AX1 of each nozzle N1 inclines to the first lateral direction SD1. By this configuration, evaporation direction MD1 also inclines to the first lateral direction SD1.

At least one of the evaporation sources DS2 to DS7 may further comprise the shield 20 as shown in FIG. 13. At least one of the evaporation sources DS2 to DS7 may further comprise the shield 30 shown in FIG. 12.

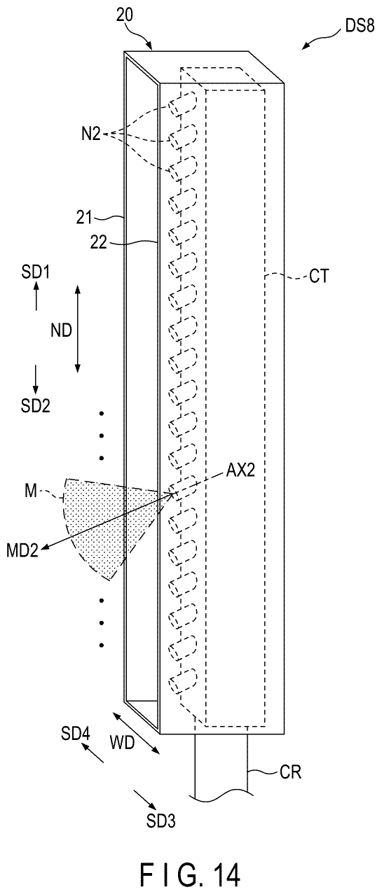

FIG. 14 is a schematic perspective view showing an example of a configuration which can be applied to the evaporation source DS8 of the upper electrode UE1. In the following explanation, each nozzle N of the evaporation source DS8 is referred to as a nozzle N2. Each nozzle N2 emits the vaporized material M in evaporation direction MD2.

Evaporation direction MD2 is, for example, parallel to axis AX2 of each nozzle N2 (the extension direction of each nozzle N2). The material M is emitted from each nozzle N2 with a predetermined spread angle based on evaporation direction MD2. Evaporation direction MD2 can be also regarded as a direction parallel to the central axis of the material M emitted from each nozzle N2, or the main emission direction of the material M. In the example of FIG. 14, axis AX2 of each nozzle N2 inclines to the second lateral direction SD2. By this configuration, evaporation direction MD2 also inclines to the second lateral direction SD2.

The evaporation source DS8 may further comprise the shield 20 as shown in FIG. 14. The evaporation source DS8 may further comprise the shield 30 shown in FIG. 12.

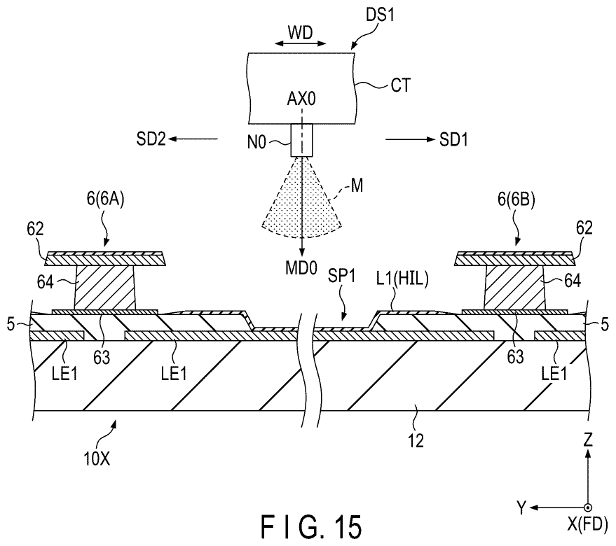

FIG. 15 is a schematic cross-sectional view showing the process of forming the hole injection layer HIL by the evaporation source DS1. The section shown in this figure corresponds to a Y-Z section similar to that of FIG. 5. The figure shows one nozzle N0 and the container CT near the nozzle N0 above the substrate 10X. However, a plurality of nozzles N0 are arranged in the horizontal direction of FIG. 15 in practice.

In the example of FIG. 15, axis AX0 of the nozzle N0 is parallel to the Z-direction (the normal direction of the substrate 10X). Thus, evaporation direction MD0 does not incline relative to the Z-direction.

As described above, the hole injection layer HIL should be preferably spaced apart from the bottom layer 63 of the partition 6. To reduce the spread of the material M emitted from the nozzle N0, the evaporation source DS1 should preferably comprise the shield 30 shown in FIG. 12. The evaporation source DS1 may further comprise the shield 20 shown in FIG. 11. When the spread of the material M is reduced, the material M is blocked by the upper portion 62 of the partition 6, and the material M is not easily attached to the lower side of the upper portion 62. This configuration can prevent the contact between the hole injection layer HIL (first layer L1) and the lower portion 61 (the bottom layer 63 and the stem layer 64).

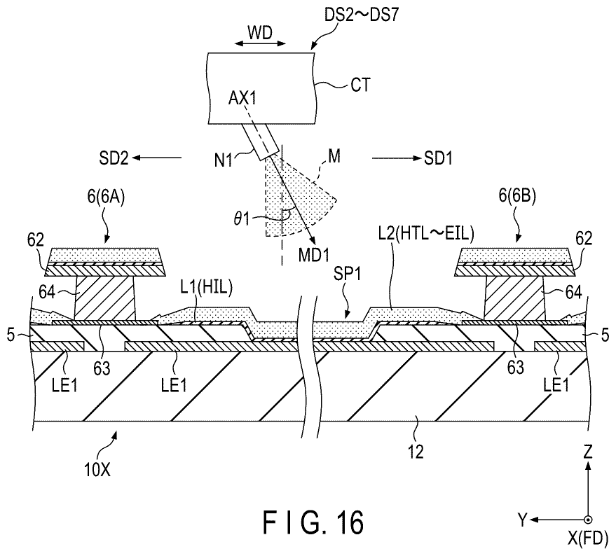

FIG. 16 is a schematic cross-sectional view showing the process of forming the hole transport layer HTL, the electron blocking layer EBL, the light emitting layer EML, the hole blocking layer HBL, the electron transport layer ETL and the electron injection layer EIL by the evaporation sources DS2 to DS7. The section shown in this figure corresponds to a Y-Z section similar to that of FIG. 15. The figure shows one nozzle N1 and the container CT near the nozzle N1 above the substrate 10X. However, a plurality of nozzles N1 are arranged in the horizontal direction of FIG. 16 in practice.

Axis AX1 of the nozzle N1 inclines to the first lateral direction SD1 relative to the Z-direction. By this configuration, axis AX1 and evaporation direction MD1 form angle θ1 which is an acute angle with the Z-direction. Each of the evaporation sources DS2 to DS7 may comprise at least one of the shields 20 and 30 described above.

When evaporation direction MD1 of the evaporation sources DS2 to DS7 inclines as shown in FIG. 16, the material M is easily attached to the vicinity of the side surface of each partition 6 on the second lateral direction SD2 side, and the material M is not easily attached to the vicinity of the side surface on the first lateral direction SD1 side. Thus, the second layer L2 whose thickness differs between the vicinities of the partitions 6A and 6B can be formed as shown in FIG. 5.

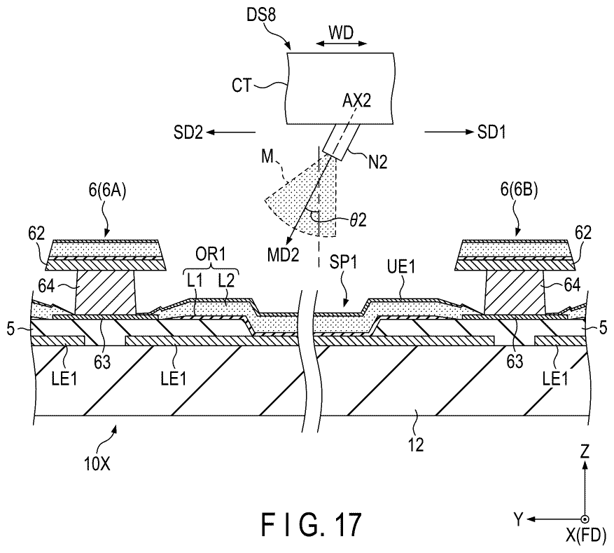

FIG. 17 is a schematic cross-sectional view showing the process of forming the upper electrode UE1 by the evaporation source DS8. The section shown in this figure corresponds to a Y-Z section similar to the sections of FIG. 15 and FIG. 16. The figure shows one nozzle N2 and the container CT near the nozzle N2 above the substrate 10X. However, a plurality of nozzles N2 are arranged in the horizontal direction of FIG. 17 in practice.

Axis AX2 of the nozzle 2 inclines to the second lateral direction SD2 relative to the Z-direction. By this configuration, evaporation direction MD2 inclines in the opposite direction of evaporation direction MD1. Axis AX2 and evaporation direction MD2 form angle θ2 which is an acute angle with the Z-direction. Angle θ2 may be equal to angle θ1 or may be different from angle θ1. The evaporation source DS8 may comprise at least one of the shields 20 and 30 described above.

When evaporation direction MD2 of the evaporation source DS8 inclines as shown in FIG. 17, the material M is easily attached to the vicinity of the side surface of each partition 6 on the first lateral direction SD1 side, and the material M is not easily attached to the vicinity of the side surface on the second lateral direction SD2 side. Thus, the upper electrode UE1 whose thickness differs between the vicinities of the partitions 6A and 6B can be formed as shown in FIG. 5.

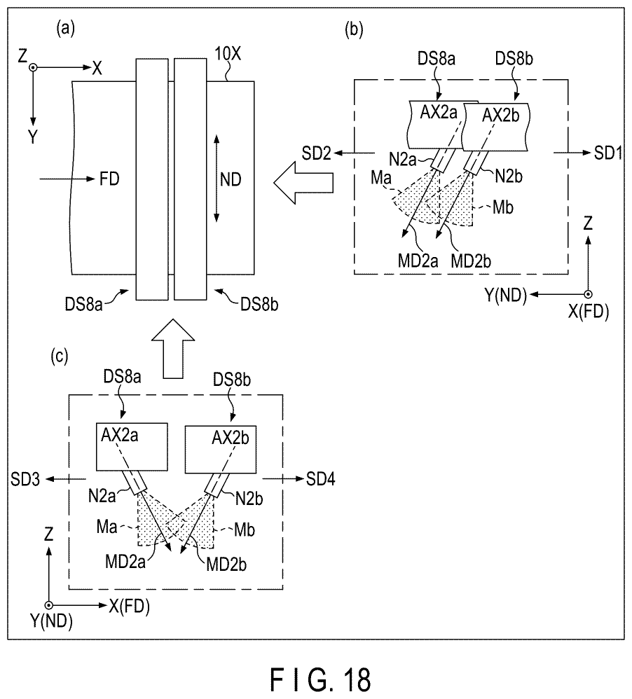

FIG. 18 is a diagram showing another example of the process of forming the upper electrode UE1. When the upper electrode UE1 is formed of an alloy of magnesium and silver as described above, the upper electrode UE1 is formed by co-evaporation of magnesium and silver.

Specifically, an evaporation source DS8a which emits material Ma which is magnesium and an evaporation source DS8b which emits material Mb which is silver are provided in the chamber C8 (see FIG. 9) of the evaporation device DD8. These evaporation sources DS8a and DS8b are provided so as to be close to each other in the moving direction FD as shown in, for example, the plan view of FIG. 18(a).

FIG. 18(b) is a schematic side view in which the evaporation sources DS8a and DS8b shown in FIG. 18(a) are viewed in the moving direction FD. FIG. 18(c) is a schematic side view in which the evaporation sources DS8a and DS8b shown in FIG. 18(a) are viewed in the nozzle alignment direction ND. As shown in FIG. 18(b) and FIG. 18(c), the evaporation source DS8a comprises a nozzle N2a, and the evaporation source DS8b comprises a nozzle N2b.

As shown in FIG. 18(b), both axis AX2a of the nozzle N2a and axis AX2b of the nozzle N2b incline to the second lateral direction SD2 relative to the Z-direction. By this configuration, evaporation direction MD2a of the evaporation source DS8a and evaporation direction MD2b of the evaporation source DS8b also incline to the second lateral direction SD2 relative to the Z-direction. For example, the angles formed by axes AX2a and AX2b (or evaporation directions MD2a and MD2b) with the Z-direction are equal to each other in FIG. 18(b).

The area to which the evaporation source DS8a emits material Ma and the area to which the evaporation source DS8b emits material Mb should preferably overlap each other on the surface of the substrate 10X. Thus, axes AX2a and AX2b incline in an X-Z plane defined by the X-direction and the Z-direction as well in FIG. 18(c).

Specifically, axis AX2a inclines to the fourth lateral direction SD4 relative to the Z-direction. Thus, evaporation direction MD2a also inclines to the fourth lateral direction SD4 relative to the Z-direction. Axis AX2b inclines to the third lateral direction SD3 relative to the Z-direction. Thus, evaporation direction MD2b also inclines to the third lateral direction SD3 relative to the Z-direction.

In this configuration, materials Ma and Mb are mixed in the moving direction FD and attached to the substrate 10X. In this manner, the upper electrode UE1 can be formed so as to have a uniform property for the entire substrate 10X.

FIG. 15 and FIG. 16 show the state in which each thin film of the organic layer OR1 is formed by one evaporation source. However, among the thin films constituting the organic layer OR1, for example, the hole injection layer HIL, the light emitting layer EML and the electron transport layer ETL could be formed by co-evaporation of a host material and a dopant. Regarding an evaporation device which forms these thin films, in a manner similar to that of the example of FIG. 18, a plurality of evaporation sources in which the axes of the nozzles (in other words, the inclinations of the evaporation direction) differ from each other may be provided in each chamber.

The configuration related to the vapor deposition of the organic layer OR1 and the upper electrode UE1 explained above with reference to FIG. 9 to FIG. 18 can be also applied to the vapor deposition of the organic layers OR2 and OR3 and the upper electrodes UE2 and UE3. Specifically, when the organic layers OR2 and OR3 and the upper electrodes UE2 and UE3 are formed, similarly, evaporation direction MD0 of the hole injection layer HIL should be parallel to the Z-direction. Further, evaporation direction MD1 of the hole transport layer HTL, the electron blocking layer EBL, the light emitting layer EML, the hole blocking layer HBL, the electron transport layer ETL and the electron injection layer EIL and evaporation direction MD2 of the upper electrodes UE2 and UE3 should incline in opposite directions.

However, when the sides S1a, S2b and S3a are set as the contact sides of subpixels SP1, SP2 and SP3, respectively, as shown in FIG. 6, evaporation directions MD1 and MD2 applied at the time of forming the organic layer OR2 and the upper electrode UE2 incline in the opposite directions of evaporation directions MD1 and MD2 applied at the time of forming the organic layer OR1 and the upper electrode UE1, respectively. By this configuration, near the side S2b, the thickness of the organic layer OR2 can be reduced, and further, the thickness of the upper electrode UE2 can be increased.

When the manufacturing method of the embodiment is used, as exemplarily shown in the structure of FIG. 5, near the contact sides, the organic layers OR1, OR2 and OR3 can be made thin, and further, the upper electrodes UE1, UE2 and UE3 can be made thick. In this manner, as explained using FIG. 5 and FIG. 6, the upper electrodes UE1, UE2 and UE3 can be satisfactorily electrically connected to the partition 6 in the contact sides.

In addition, in the embodiment, evaporation directions MD1 and MD2 of the evaporation sources DS2 to DS8 incline to a direction (the first lateral direction SD1 or the second lateral direction SD2) orthogonal to the moving direction FD. This configuration is advantageous when co-evaporation is performed as shown in FIG. 18. Specifically, in a configuration in which evaporation directions MD1 and MD2 incline to a direction (the third lateral direction SD3 or the fourth lateral direction SD4) parallel to the moving direction FD, the materials emitted from a plurality of evaporation sources for co-evaporation may not be easily satisfactorily mixed in the moving direction FD in some cases. If the areas to which these materials are attached on the substrate 10X deviate from each other in the moving direction FD, the film formed by vapor deposition could have unevenness in properties (for example, unevenness in the concentration of a dopant) in the thickness direction.

To the contrary, when evaporation directions MD1 and MD2 incline to a direction (the first lateral direction SD1 or the second lateral direction SD2) orthogonal to the moving direction FD, the materials emitted from the evaporation sources can be satisfactorily mixed in the moving direction FD by inclining the evaporation directions of the evaporation sources in directions parallel to the moving direction FD as shown in, for example, FIG. 18(c). In this configuration, unevenness in properties in the thickness direction is not easily caused in the films formed by vapor deposition.

It should be noted that the hole transport layer HTL, the electron blocking layer EBL, the light emitting layer EML, the hole blocking layer HBL, the electron transport layer ETL and the electron injection layer EIL are examples of a first thin film formed by inclining the axis of each nozzle in the manufacturing method exemplarily shown in FIG. 9 to FIG. 18. Further, the hole injection layer HIL is an example of a second thin film formed without inclining the axis of each nozzle.

As another example, all of the thin films constituting the organic layer OR1 including the hole injection layer HIL may be formed by using nozzles having axes inclining relative to the Z-direction in a manner similar to that of the example of FIG. 16. At least one of the hole transport layer HTL, the electron blocking layer EBL, the light emitting layer EML, the hole blocking layer HBL, the electron transport layer ETL and the electron injection layer EIL may be formed by using nozzles having axes parallel to the Z-direction in a manner similar to that of the example of FIG. 15.

In other words, at least one of the thin films constituting the organic layer OR1 should be formed by using nozzles having axes inclining in the opposite direction of the nozzles N2 of the upper electrode UE1. By this configuration, the organic layer OR1 is made thin in the contact side in which the upper electrode UE1 is formed so as to be thick. Therefore, the conduction between the upper electrode UE1 and the partition 6 is improved compared to a case where all of the thin films are formed using nozzles having axes parallel to the Z-direction.

The evaporation direction of at least one of the thin films constituting the organic layer OR1 may be inclined to the same direction as the evaporation direction of the upper electrode UE1 at an angle less than the evaporation direction of the upper electrode UE1. In this case, similarly, the upper electrode UE1 can be formed so as to be closer to the lower portion 61 than the organic layer OR1 in the contact side.

As yet another example, all of the thin films constituting the organic layer OR1 may be formed by using nozzles having axes parallel to the Z-direction. p Alternatively, at least one of the thin films constituting the organic layer OR1 may be formed by using nozzles having axes inclining relative to the Z-direction, and the upper electrode UE1 may be formed by using nozzles having axes parallel to the Z-direction.

In the manufacturing method exemplarily shown in FIG. 9 to FIG. 18, this specification exemplarily shows the configuration in which the substrate 10X relatively moves with respect to the still evaporation sources DS1 to DS8 as the substrate 10X is conveyed in the moving direction FD by the conveyance device CD. As another example, when the evaporation sources DS1 to DS8 perform vapor deposition, the substrate 10X may stand still in each of the chambers C1 to C8, and the evaporation sources DS1 to DS8 may relatively move with respect to this substrate 10X. In this case, for example, the evaporation sources DD1 to DD8 comprise respective driving mechanisms for moving the respective evaporation sources DS1 to DS8 in the respective chambers C1 to C8.

The modified examples described above regarding the organic layer OR1 and the upper electrode UE1 can be applied to the organic layers OR2 and OR3 and the upper electrodes UE2 and UE3 in a similar manner.

The configuration of the partition 6 is not limited to FIG. 5 etc. Several modified examples which could be applied to the partition 6 are shown below.

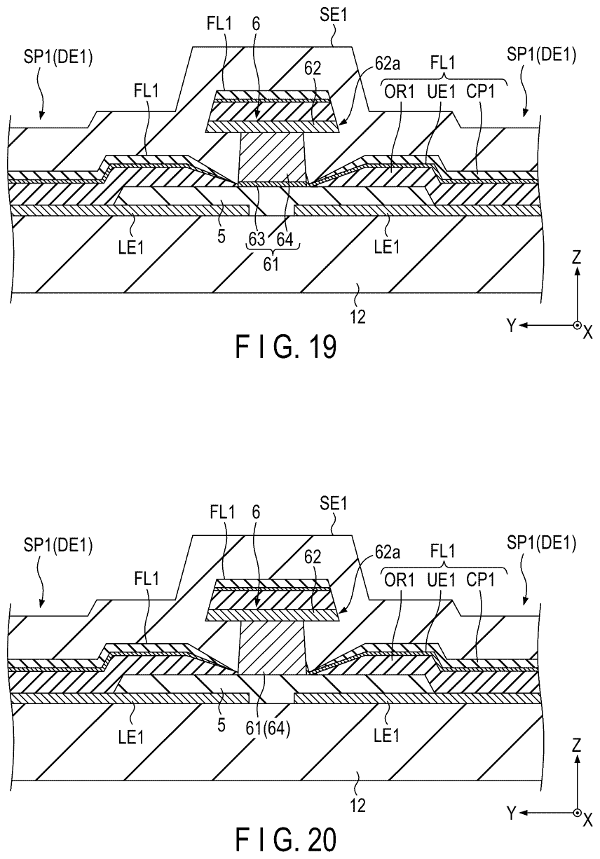

FIG. 19 is a schematic cross-sectional view showing the first modified example of a configuration which could be applied to the partition 6. In the example of this figure, the both end portions of the bottom layer 63 are aligned with the side surfaces of the stem layer 64. The right side surface of the partition 6 shown in the figure corresponds to the contact side with the upper electrode UE1. Thus, the upper electrode UE1 of the right subpixel SP1 in the figure is in contact with the side surfaces of the bottom layer 63 and the stem layer 64. To the contrary, the organic layer OR1 of the right subpixel SP1 is spaced apart from the side surfaces of the bottom layer 63 and the stem layer 64. As another example, this organic layer OR1 may be in contact with the side surfaces of the bottom layer 63 and the stem layer 64.

FIG. 20 is a schematic cross-sectional view showing the second modified example of a configuration which could be applied to the partition 6. In the example of this figure, the lower portion 61 does not comprise the bottom layer 63. Thus, the lower portion 61 consists of the stem layer 64. In this figure, similarly, the right side surface of the partition 6 corresponds to the contact side, and the upper electrode UE1 is in contact with this side surface. In a manner similar to that of the example of FIG. 19, the organic layer OR1 of the right subpixel SP1 is spaced apart from the side surface of the stem layer 64. As another example, this organic layer OR1 may be in contact with the side surface of the stem layer 64.

All of the display devices, and the manufacturing methods and manufacturing equipment of the display devices that can be implemented by a person of ordinary skill in the art through arbitrary design changes to the display device, manufacturing method and manufacturing equipment described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A manufacturing method of a display device, the method including:
preparing a substrate including a lower electrode, a rib having a pixel aperture which overlaps the lower electrode, and a partition having a conductive lower portion provided on the rib and an upper portion which protrudes from a side surface of the lower portion;
forming an organic layer which is in contact with the lower electrode through the pixel aperture and emits light based on application of voltage by vapor deposition for the substrate; and
forming an upper electrode which covers the organic layer and is in contact with the lower portion of the partition by vapor deposition for the substrate, wherein
the organic layer includes a first thin film,
a first evaporation source used to form the first thin film comprises a first nozzle which emits a vaporized material toward the substrate which relatively moves with respect to the first evaporation source,
a second evaporation source used to form the upper electrode comprises a second nozzle which emits a vaporized material toward the substrate which relatively moves with respect to the second evaporation source, and
an axis of at least one of the first nozzle and the second nozzle inclines to a direction orthogonal to a moving direction of the substrate in plan view with respect to a normal direction of the substrate.

2. The manufacturing method of claim 1, wherein
the axis of the first nozzle inclines to a first lateral direction orthogonal to the moving direction in plan view with respect to the normal direction, and
the axis of the second nozzle inclines to a second lateral direction opposite to the first lateral direction with respect to the normal direction.

3. The manufacturing method of claim 2, wherein
the first evaporation source comprises the first nozzles arranged in a direction orthogonal to the moving direction in plan view, and
the axis of each of the first nozzles inclines to the first lateral direction.

4. The manufacturing method of claim 2, wherein
the second evaporation source comprises the second nozzles arranged in a direction orthogonal to the moving direction in plan view, and
the axis of each of the second nozzles inclines to the second lateral direction.

5. The manufacturing method of claim 2, wherein
the organic layer includes a second thin film,
a third evaporation source used to form the second thin film comprises a third nozzle which emits a vaporized material, and
an axis of the third nozzle is parallel to the normal direction.

6. The manufacturing method of claim 5, wherein
the first thin film is one of a hole transport layer, an electron blocking layer, a light emitting layer, a hole blocking layer, an electron transport layer and an electron injection layer.

7. The manufacturing method of claim 6, wherein
the second thin film is a hole injection layer.

8. The manufacturing method of claim 2, wherein
the partition has first and second partitions provided such that the pixel aperture is interposed between the first and second partitions,
the upper portion of the first partition has a first end portion,
the upper portion of the second partition has a second end portion, and
the organic layer is formed such that a thickness immediately under the first end portion is less than a thickness immediately under the second end portion.

9. The manufacturing method of claim 8, wherein
the upper electrode is formed such that a thickness immediately under the first end portion is greater than a thickness immediately under the second end portion.

10. The manufacturing method of claim 1, wherein
when the first thin film and the upper electrode are formed, the substrate is moved relative to the first and second evaporation sources which stand still.

11. The manufacturing method of claim 1, wherein
when the first thin film and the upper electrode are formed, the first evaporation source and the second evaporation source are moved relative to the substrate which stands still.

12. A manufacturing equipment of a display device, the manufacturing equipment comprising:
a first evaporation device which forms, for a substrate including a lower electrode, a rib having a pixel aperture which overlaps the lower electrode, and a partition having a conductive lower portion provided on the rib and an upper portion which protrudes from a side surface of the lower portion, an organic layer which is in contact with the lower electrode through the pixel aperture and emits light based on application of voltage; and
a second evaporation device which forms an upper electrode which covers the organic layer and is in contact with the lower portion of the partition for the substrate, wherein
the organic layer includes a first thin film,
the first evaporation device comprises a first evaporation source comprising a first nozzle which emits a vaporized material of the first thin film toward the substrate which relatively moves with respect to the first evaporation source,
the second evaporation device comprises a second evaporation source comprising a second nozzle which emits a vaporized material of the upper electrode toward the substrate which relatively moves with respect to the second evaporation source, and
an axis of at least one of the first nozzle and the second nozzle inclines to a direction orthogonal to a moving direction of the substrate in plan view with respect to a normal direction of the substrate.

13. The manufacturing equipment of claim 12, wherein
the axis of the first nozzle inclines to a first lateral direction orthogonal to the moving direction in plan view with respect to the normal direction, and
the axis of the second nozzle inclines to a second lateral direction opposite to the first lateral direction with respect to the normal direction.

14. The manufacturing equipment of claim 13, wherein
the first evaporation source comprises the first nozzles arranged in a direction orthogonal to the moving direction in plan view, and
the axis of each of the first nozzles inclines to the first lateral direction.

15. The manufacturing equipment of claim 13, wherein
the second evaporation sources comprise the second nozzles arranged in a direction orthogonal to the moving direction in plan view, and
the axis of each of the second nozzles inclines to the second lateral direction.

16. The manufacturing equipment of claim 13, wherein
the organic layer includes a second thin film, a third evaporation source used to form the second thin film comprises a third nozzle which emits a vaporized material, and
an axis of the third nozzle is parallel to the normal direction.

17. The manufacturing equipment of claim 16, wherein
the first thin film is one of a hole transport layer, an electron blocking layer, a light emitting layer, a hole blocking layer, an electron transport layer and an electron injection layer.

18. The manufacturing equipment of claim 17, wherein
the second thin film is a hole injection layer.

19. The manufacturing equipment of claim 12, wherein
when the first thin film and the upper electrode are formed, the substrate is moved relative to the first and second evaporation sources which stand still.

20. The manufacturing equipment of claim 12, wherein
when the first thin film and the upper electrode are formed, the first evaporation source and the second evaporation source are moved relative to the substrate which stands still.
